(19) United States
(12) Patent Application Publication
(10) Pub. No.: US 2026/0346378 A1
(43) Pub. Date: Nov. 5, 2026

(54) SUBSTRATE PROCESSING METHOD AND SUBSTRATE PROCESSING SYSTEM

(71) Applicant: Tokyo Electron Limited, Tokyo (JP)

(72) Inventors: Kazuhiro SHIBA, Kikuchi-gun, Kumamoto (JP); Susumu HAYAKAWA, Kikuchi-gun, Kumamoto (JP); Yohei YAMASHITA, Kikuchi-gun, Kumamoto (JP); Yosuke NAKAMURA, Kikuchi-gun, Kumamoto (JP); Kento ARAKI, Kikuchi-gun, Kumamoto (JP); Yoshihiro KAWAGUCHI, Kikuchi-gun, Kumamoto (JP); Katsusuke HIBI, Kikuchi-gun, Kumamoto (JP)

(21) Appl. No.: 19/125,437

(22) PCT Filed: Oct. 18, 2023
(86) PCT No.: PCT/JP2023/037668

§ 371 Date: Apr. 29, 2025

(30) Foreign Application Priority Data
Oct. 31, 2022 (JP) 2022-174488

(51) Int. Cl. B23K 26/53; B23K 26/16; B23K 26/70; B23K 101/40; H10P 34/42

(52) U.S. Cl. CPC B23K 26/53; B23K 26/16; B23K 26/706; H10P 34/42; B23K 2101/40

(57) ABSTRACT

A substrate processing method of processing a substrate includes applying laser light to the substrate to form a modification layer and a crack; acquiring data on a cumulative number of processed substrates, a contamination amount on a cover glass that protects a condenser lens for focusing the laser light, a flow rate of a gas supplied along a bottom surface of the cover glass, and a length of the crack that develops due to the applying of the laser light; and controlling the applying of the laser light based on the acquired data.

### TECHNICAL FIELD

The various aspects and embodiments described herein pertain generally to a substrate processing method and a substrate processing system.

### BACKGROUND

Patent document 1 discloses a processing apparatus that performs a laser processing on a workpiece by using laser radiation device. This processing apparatus is equipped with a condenser configured to focus laser beams, and the condenser is equipped with an objective lens and a lens protection cover serving to block debris scattered from the workpiece to suppress contamination of the objective lens. In the processing apparatus described in Patent Document 1, contamination of the lens protection cover is detected by an imaging device.

### PRIOR ART DOCUMENT

Patent Document 1: Japanese Patent Laid-open Publication No. 2012-179642

### DISCLOSURE OF THE INVENTION

### Problems to be Solved by the Invention

Exemplary embodiments provide a substrate processing method capable of appropriately managing and estimating processing quality in a substrate processing in which a modification layer is formed in a substrate by a laser processing and cracks are developed from the modification layer.

### Means For Solving the Problems

In an exemplary embodiment, a substrate processing method of processing a substrate includes applying laser light to the substrate to form a modification layer and a crack that develops in a thickness direction of the substrate from the modification layer; acquiring data on a cumulative number of processed substrates, a contamination amount on a cover glass that protects a condenser lens configured to focus the laser light, a flow rate of a gas supplied along a bottom surface of the cover glass, and a length of the crack that develops due to the applying of the laser light; and controlling the applying of the laser light based on the acquired data.

### Effect of the Invention

According to the exemplary embodiments, it is possible to provide the substrate processing method capable of appropriately managing and estimating the processing quality in the substrate processing in which the modification layer is formed in the substrate by the laser processing and the cracks are developed from the modification layer.

### BRIEF DESCRIPTION OF THE DRAWINGS

FIG. 1 is a side view illustrating an example of a combined wafer to be processed in a wafer processing system.

FIG. 2 is a plan view illustrating a schematic configuration example of a wafer processing system according to an exemplary embodiment.

FIG. 3 is a plan view illustrating a configuration example of an internal modifying apparatus.

FIG. 4 is a side view illustrating the configuration example of the internal modifying apparatus.

FIG. 5 is a cross sectional view illustrating a detailed configuration of a laser radiation device.

FIG. 6A to FIG. 6D are explanatory diagrams illustrating a series of processes of a wafer processing in the wafer processing system.

FIG. 7 is a flowchart showing main processes of detecting contamination on a cover glass.

FIG. 8 is a schematic diagram showing an example of an imaging result by a lens imaging mechanism.

FIG. 9 is a schematic diagram illustrating an example of a captured image whose brightness and contrast have been adjusted.

FIG. 10 is a diagram illustrating an example histogram of the luminance of the captured image.

FIG. 11 is a schematic diagram illustrating an example result of binarizing the captured image.

FIG. 12 provides a histogram showing an example result of detecting contamination on the cover glass.

FIG. 13 presents a graph showing a relationship between an estimated value and an actual value of BHC.

FIG. 14 presents a graph showing a relationship between BHC and a contamination amount of the cover glass.

### DETAILED DESCRIPTION

In a manufacturing process for a semiconductor device, in a combined wafer in which a first wafer, which is a semiconductor substrate (hereinafter, simply referred to as “wafer”) having a multiple number of devices such as electronic circuits formed on a front surface thereof, and a second wafer are bonded to each other, removal of a peripheral portion of the first wafer, that is, so-called edge trimming may be performed.

For example, in the edge trimming of the first wafer, a modification layer is formed by applying laser light to an inside of the first wafer from a laser radiation device, a crack is developed in a thickness direction of the first wafer, and the peripheral portion is removed from the first wafer, starting from the modification layer and the crack. The laser light for forming the modification layer is applied from a laser head to the first wafer through a lens.

In the formation of the modification layer in the first wafer, particles are generated due to the laser processing of the first wafer. If the generated particles adhere to the lens, the processing quality will decrease. Therefore, as disclosed in Patent Document 1, the laser radiation device is provided with a cover glass (lens protection cover) on the lens (objective lens) to suppress the adhesion of the particles (debris) to the lens, and, also, air is supplied along a bottom surface of the cover glass to suppress adhesion of the particles to the cover glass.

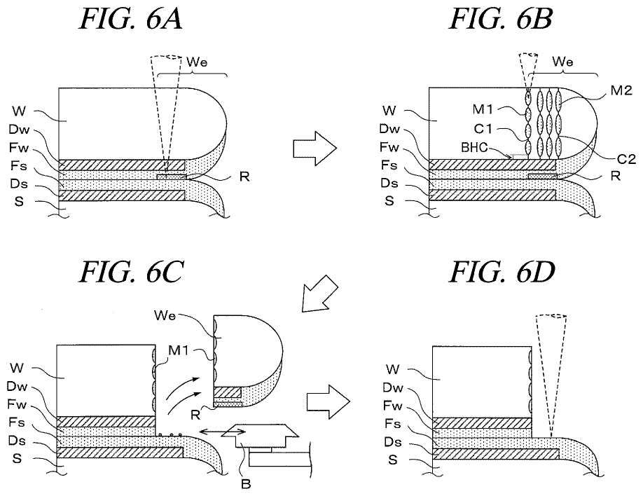

Here, the inventors of the present application have conducted intensive research and found that there is a correlation between a contamination amount due to the adhesion of the particles to the lens, the number of processed combined wafers (first wafers), the flow rate of the air supplied to the bottom surface of the cover glass, and BHC. Here, “BHC” refers to the length of a crack C1 (see FIG. 6B) propagating from, among peripheral modification layers M1 formed inside the first wafer by the laser processing as will be described later, the peripheral modification layer M1 formed closest to a front surface of the first wafer (the surface to be bonded to the second wafer) toward this front surface. The inventors of the present application also have found the possibility of appropriately managing and estimating the processing quality of the edge trimming of the first wafer by using this correlation. Patent Document 1 does not mention or suggest such a correlation between the contamination amount, the number of processed wafers, the flow rate of the air, and the BHC.

The technology of the present disclosure provides a substrate processing method capable of appropriately managing and estimating processing quality in a substrate processing in which a modification layer is formed in a substrate by a laser processing and a crack is developed from the modification layer. Hereinafter, a wafer processing system as a substrate processing system and a wafer processing method as a substrate processing method according to an exemplary embodiment will be explained with reference to the accompanying drawings. Further, in the present specification and the accompanying drawings, parts having substantially the same functions and configurations will be assigned same reference numerals, and redundant descriptions thereof will be omitted.

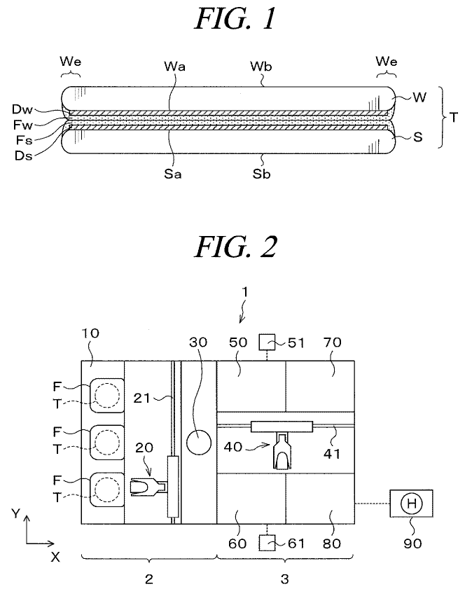

In a wafer processing system 1 according to the present exemplary embodiment, which will be described later, a processing is performed on a combined wafer T in which a first wafer W as a substrate and a second wafer S are bonded to each other, as illustrated in FIG. 1. Hereinafter, a surface of the first wafer W bonded to the second wafer S will be referred to as a front surface Wa, and a surface opposite the front surface Wa will be referred to as a rear surface Wb. Likewise, a surface of the second wafer S bonded to the first wafer W will be referred to as a front surface Sa, and a surface opposite the front surface Sa will be referred to as a rear surface Sb.

The first wafer W is a semiconductor substrate such as, but not limited to, a silicon substrate, and a device layer Dw including multiple devices is formed on the front surface Wa. Also, a bonding film Fw is further formed on the device layer Dw, and the device layer Dw is bonded to the second wafer S with the bonding film Fw therebetween. The bonding film Fw may be, by way of example, an oxide film (a THOX film, a SiO₂ film, a TEOS film), a SIC film, a SiCN film, or an adhesive. A peripheral portion We of the first wafer W is chamfered, and the thickness of this peripheral portion We decreases toward a leading end thereof on a cross section thereof. The peripheral portion We is a portion to be removed in edge trimming to be described later, and is in the range of, e.g., 0.5 mm to 3 mm from an edge of the first wafer W in a radial direction.

The second wafer S has, for example, the same structure as the first wafer W, and a device layer Ds and a bonding film Fs are formed on the front surface Sa, and a peripheral portion of the second wafer S is chamfered. However, the second wafer S does not need to be a device wafer on which the device layer Ds is formed, but it may be, for example, a support wafer that supports the first wafer W.

As shown in FIG. 2, the wafer processing system 1 has a configuration in which a carry-in/out station 2 and a processing station 3 are connected as a single structure. In the carry-in/out station 2, a FOUP F capable of accommodating therein a plurality of combined wafers T is carried to/from the outside, for example. The processing station 3 is equipped with various types of processing apparatuses each configured to perform a required processing on the combined wafers T.

The carry-in/out station 2 is equipped with a FOUP placement table 10 on which the FOUP F capable of accommodating therein the plurality of combined wafers T is placed. Further, a wafer transfer device 20 is provided adjacent to the FOUP placement table 10 on the positive X-axis side of the FOUP placement table 10. The wafer transfer device 20 is configured to be moved on a transfer path 21 extending in the Y-axis direction to transfer the combined wafers T between the FOUP F of the FOUP placement table 10 and a transition device 30 to be described later.

In the carry-in/out station 2, the transition device 30 configured to deliver the combined wafers T to/from the processing station 3 is provided adjacent to the wafer transfer device 20 on the positive X-axis side of the wafer transfer device 20.

Disposed in the processing station 3 are a wafer transfer device 40, an interface modifying apparatus 50, an internal modifying apparatus 60, a periphery removing apparatus 70, and a cleaning apparatus 80.

The wafer transfer device 40 is provided on the positive X-axis side of the transition device 30. The wafer transfer device 40 is configured to be movable on a transfer path 41 extending in the X-axis direction to transfer the combined wafers T to/from the transition device 30 of the carry-in/out station 2, the interface modifying apparatus 50, the internal modifying apparatus 60, the periphery removing apparatus 70 and the cleaning apparatus 80.

The interface modifying apparatus 50 is configured to apply laser light (interface laser light such as a CO₂ laser) to an interface between the first wafer W and the second wafer S to form a bonding strength reduction region R (see FIG. 6A) in which the bonding strength between the first wafer W and the second wafer S is reduced. The configuration of the interface modifying apparatus 50 is not particularly limited. The interface modifying apparatus 50 has a control device 51 to be described later.

The internal modifying apparatus 60 is configured to apply laser light (internal laser light such as a YAG laser or a fiber laser) to an inside of the first wafer W to form the peripheral modification layer M1 serving as a starting point for separation of the peripheral portion We and a split modification layer M2 serving as a starting point for breaking the peripheral portion We into small pieces (see FIG. 6B). The internal modifying apparatus 60 has a control device 61 to be described later.

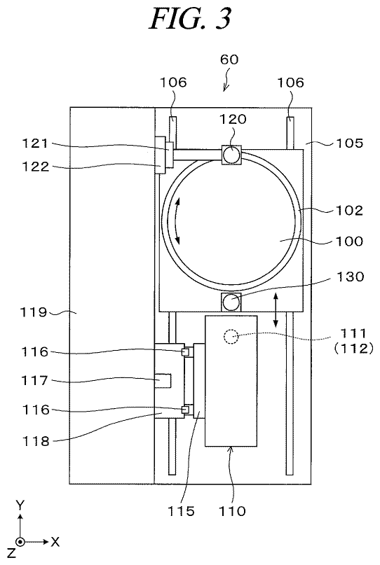

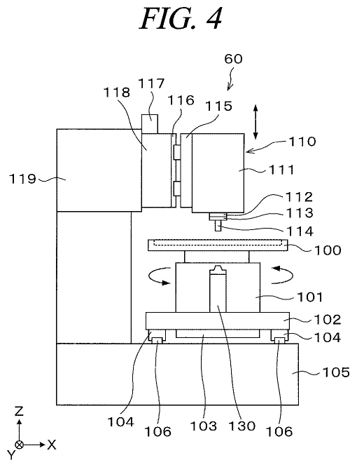

As illustrated in FIG. 3 and FIG. 4, the internal modifying apparatus 60 has a chuck 100 configured to hold the combined wafer T on a top surface thereof. The chuck 100 attracts and holds the rear surface Sb of the second wafer S, with the first wafer W, which is a target on which the peripheral modification layer M1 is to be formed, positioned on the upper side and the second wafer S positioned on the lower side. The chuck 100 is supported by a slider table 102 with an air bearing 101 therebetween. A rotating mechanism 103 is provided on a bottom surface of the slider table 102. The rotating mechanism 103 has, for example, a motor as a driving source embedded therein. The chuck 100 is configured to be rotatable around a vertical axis by the rotating mechanism 103 via the air bearing 101. The slider table 102 is configured to be movable on a rail 106 extending on a base 105 in the Y-axis direction by a moving mechanism 104 provided on a bottom surface thereof. Further, although not particularly limited, a driving source of the moving mechanism 104 may be, by way of non-limiting example, a linear motor.

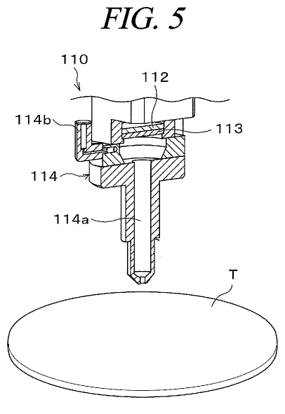

A laser radiation device 110 is disposed above the chuck 100 to apply laser light to the combined wafer T (first wafer W) held by the chuck 100. The laser radiation device 110 has, as shown in FIG. 5, a laser head 111, a condenser lens 112, a cover glass 113, and a nozzle 114. The laser light applied from the laser radiation device 110 to the combined wafer T (first wafer W) is supplied from a non-illustrated laser oscillator.

The laser head 111 is supported by a supporting member 115. The laser head 111 is configured to be movable up and down by an elevating mechanism 117 along a rail 116 extending in a vertical direction. The laser head 111 is also configured to be movable in the Y-axis direction by a moving mechanism 118. The elevating mechanism 117 and the moving mechanism 118 are supported by a supporting column 119.

The condenser lens 112 is provided on a bottom surface of the laser head 111, and serves to focus the laser light from the laser oscillator and direct it to an inside of the combined wafer T held by the chuck 100, more specifically, to an inside of the first wafer W. As a result, portions inside the first wafer W irradiated with the laser light are modified, so that the peripheral modification layer M1 and the split modification layer M2 are formed. Further, the crack C develops in a thickness direction of the first wafer W from the peripheral modification layer M1 and the split modification layer M2 formed by the radiation of the laser light, as will be described later.

The cover glass 113 is a member provided on a bottom surface of the condenser lens 112, and serves to suppress particles generated by the radiation of the laser light to the combined wafer T (first wafer W) (laser processing of the first wafer W) from adhering to the condenser lens 112.

The nozzle 114 is provided under the condenser lens 112. The nozzle 114 is a hollow cylindrical member having an internal space 114a, and the laser light from the condenser lens 112 passes through the internal space 114a to be applied to the first wafer W.

A gas feed section 114b is provided above the nozzle 114 to supply a gas such as air, nitrogen (N₂), or the like to an inside of the nozzle 114. The gas feed section 114b communicates with the internal space 114a. The gas supplied from the gas feed section 114b is laterally supplied into the internal space 114a along the bottom surface of the cover glass 113, and then flows downwards through the internal space 114a and the nozzle 114 and is jetted to the rear surface Wb of the first wafer W. This gas suppresses the particles generated by the laser processing from adhering to the bottom surface of the cover glass 113. The particles removed from the rear surface Wb of the first wafer W by the gas from the nozzle 114 are collected by a non-illustrated dust collector.

A wafer imaging mechanism 120 is provided above the chuck 100 on the positive Y-axis side of the laser radiation device 110. In the internal modifying apparatus 60, the combined wafer T (first wafer W) held on the chuck 100 is imaged by the wafer imaging device 120, and based on the captured image, the first wafer W is aligned and the radiation position of the laser light is determined.

A lens imaging mechanism 130 is provided on the negative Y-axis side of the chuck 100. The lens imaging mechanism 130 includes one or more cameras. The lens imaging mechanism 130 is disposed, for example, on the slider table 102, and is configured to be movable in the Y-axis direction together with the chuck 100 by the moving mechanism 104.

In the internal modifying apparatus 60, the cover glass 113 of the laser radiation device 110 is imaged from below by the lens imaging mechanism 130, and a contamination amount on the cover glass 113 is detected based on the image thus obtained.

The periphery removing apparatus 70 is configured to perform the removal of the peripheral portion We of the first wafer W starting from the peripheral modification layer M1 formed in the internal modifying apparatus 60, that is, the edge trimming. A method of the edge trimming is not particularly limited. As an example, in the periphery removing apparatus 70, a blade formed in a wedge shape may be inserted into the interface between the first wafer W and the second wafer S. As another example, air or a water jet may be blown toward the peripheral portion We to apply an impact to the peripheral portion We.

The cleaning apparatus 80 is configured to perform a cleaning processing on the first wafer W and the second wafer S after being subjected to the edge trimming in the periphery removing apparatus 70 to remove particles on these wafers. A method of the cleaning is not particularly limited.

The above-described wafer processing system 1 is provided with the control device 51, the control device 61, and a control device 90. The control device 51 independently controls the operation of the interface modifying apparatus 50. The control device 61 independently controls the operation of the internal modifying apparatus 60. The control device 90 performs an overall control over the series of processes of the wafer processing in the wafer processing system 1. The control devices 51, 61, and 90 are, for example, computers each equipped with a CPU, a memory, and the like, and each has a program storage (not shown). The program storage stores therein a program for controlling the processing of the combined wafer T. The program may have been recorded on a computer-readable recording medium H, and may be installed from this recording medium H. The recording medium H may be transitory or non-transitory.

In the present exemplary embodiment, the control device 51 and the control device 61 are installed separately for the interface modifying apparatus 50 and the internal modifying apparatus 60, respectively. However, the control device 51 and the control device 61 may be integrated with the control device 90. In other words, the operations of the interface modifying apparatus 50 and the internal modifying apparatus 60 may be controlled by the control device 90.

Now, a wafer processing performed by using the wafer processing system 1 configured as described above will be explained. In the present exemplary embodiment, the first wafer W and the second wafer S are bonded to each other to form the combined wafer T in advance.

First, the FOUP F accommodating the plurality of combined wafers T is placed on the FOUP placement table 10 of the carry-in/out station 2. Then, the combined wafer T is taken out from the FOUP F by the wafer transfer device 20, and transferred to the interface modifying apparatus 50 via the transition device 30 and the wafer transfer device 40.

In the interface modifying apparatus 50, while rotating the combined wafer T and also moving it horizontally along the Y-axis direction, the interface laser light is applied in pulses to an inside of the combined wafer T, specifically, to the interface between the first wafer W and the second wafer S. As a result, as shown in FIG. 6A, the interface between the first wafer W and the second wafer S (the interface between the bonding films Fw and Fs in the shown example) is modified. The modification of the bonding interface in the exemplary embodiment includes amorphization of the bonding film Fw at the radiation position of the interface laser light, the separation of the interface between the first wafer W and the second wafer S, and the like.

In the interface modifying apparatus 50, the irradiation portion of the interface laser light at the interface between the first wafer W and the second wafer W is modified in this manner, so that the bonding strength reduction region R in which the bonding strength between the first wafer W and the second wafer S is reduced is formed. In the edge trimming to be described later, the peripheral portion We of the first wafer W, which is a target to be removed, is removed, and the presence of this bonding strength reduction region R enables appropriate removal of the peripheral portion We.

Further, the interface laser light may be applied to the combined wafer T from the rear surface Sb side of the second wafer S, or from the rear surface Wb side of the first wafer W.

The combined wafer T having the bonding strength reduction region R formed at the interface between the first wafer W and the second wafer S is then transferred by the wafer transfer device 40 to the internal modifying apparatus 60.

In the internal modifying apparatus 60, the internal laser light is applied to an inside of the first wafer W as shown in FIG. 6B to form the peripheral modification layer M1 and the split modification layer M2. Also, the crack C1 and a crack C2 develop in the thickness direction of the first wafer W from the peripheral modification layer M1 and the split modification layer M2 formed by the irradiation of the internal laser light, respectively. Like the peripheral modification layer M1, the crack C1 serves as a starting point for removing the peripheral portion We. Like the split modification layer M2, the crack C2 serves as a starting point for breaking the peripheral portion We into small pieces. In the drawings to be referred to in the following description, illustration of the split modification layer M2 and the crack C2 may be omitted in order to avoid the illustration becoming complicated.

In addition, particles are generated during the formation of the peripheral modification layer M1 (laser processing) in the peripheral modifying apparatus 60. The particles generated by the laser processing of the first wafer W are removed from the first wafer W by the gas from the nozzle 114 as stated above. However, when the flow rate of the gas supplied from the nozzle 114 is high, the particles may be swept upwards and adhere to the bottom surface of the cover glass 113. If the particles adhere to the cover glass 113, the processing quality deteriorates. Specifically, the length (BHC) of the crack C1 extending toward the front surface Wa of the first wafer W from the peripheral modification layer M1 formed at the lowermost portion inside the first wafer W (the front surface Wa side bonded to the second wafer S) becomes shorter, so the crack C1 may not reach the front surface Wa, resulting in a failure to properly remove the peripheral portion We.

As a resolution, in the internal modifying apparatus 60 according to the technology of the present disclosure, correlation data between the flow rate of the gas supplied from the nozzle 114, the number of processed combined wafers T (first wafers W) (the cumulative number of processed wafers in the internal modifying apparatus 60), the contamination amount (more specifically, luminance to be described later) of the cover glass 113, and the BHC are acquired, and the laser processing in the internal modifying apparatus 60 is controlled based on the acquired correlation data. A detailed method of controlling the laser processing using the correlation data will be elaborated later.

The combined wafer T, in which the peripheral modification layer M1 and the split modification layer M2 are formed inside the first wafer W, is then transferred to the periphery removing apparatus 70 by the wafer transfer device 40.

In the periphery removing apparatus 70, removal of the peripheral portion We of the first wafer W, that is, edge trimming is performed, as shown in FIG. 6C. At this time, the peripheral portion We is separated from a central portion (radially inside the peripheral portion We) of the first wafer W starting from the peripheral modification layer M1 and the crack C1, and is completely separated from the second wafer S starting from the bonding strength reduction region R. At this time, the peripheral portion We being removed is also split into small pieces starting from the split modification layer M2 and the crack C2. In removing the peripheral portion We, a blade B (see FIG. 6C) having a wedge shape, for example, may be inserted into the interface between the first wafer W and the second wafer S forming the combined wafer T.

The combined wafer T from which the peripheral portion We of the first wafer W has been removed is then transferred to the cleaning apparatus 80 by the wafer transfer device 40.

In the cleaning apparatus 80, the first wafer W with its peripheral portion We removed, and/or the second wafer S are cleaned. For example, in the cleaning apparatus 80, as illustrated in FIG. 6D, by applying cleaning laser light to the first wafer W and/or the second wafer S, an irradiation portion of the cleaning laser light may be modified and removed, thereby removing (cleaning) particles or the like remaining thereon.

Thereafter, the combined wafer T after being subjected to all the required processes is transferred to the transition device 30 by the wafer transfer device 40, and then transferred to the FOUP F of the FOUP placement table 10 by the wafer transfer device 20. In this way, the series of processes of the wafer processing in the wafer processing system 1 are completed.

Now, a detailed method of controlling the laser processing using the correlation data in the above-described internal modifying apparatus 60 will be discussed with reference to the accompanying drawings.

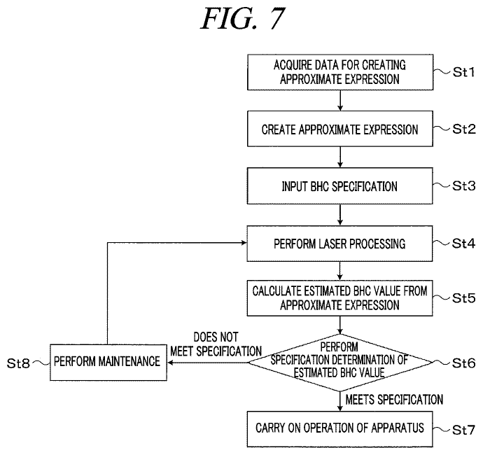

In the laser processing control according to the present disclosure, various data for creating an approximate expression (2) to be described later are first acquired (process St1 in FIG. 7). Specifically, in the present exemplary embodiment, the flow rate of the gas supplied from the nozzle 114 during the laser processing, the number of processed combined wafers T (first wafers W), and the contamination amount of the cover glass 113 are acquired as the various data for creating the approximate expression.

The flow rate of the gas from the nozzle 114 may be obtained based on, for example, a processing recipe and a processing result of the combined wafer T (first wafer W).

The number of processed combined wafers T (first wafers W) is the cumulative number of processed combined wafers (first wafers W) that have been laser-processed by the internal modifying apparatus 60 between the time of the previous data acquisition and the time of the current data acquisition.

To quantify the contamination amount of the cover glass 113, the cover glass 113 may be located above the lens imaging mechanism 130 by moving the chuck 100, and in this state, the cover glass 113 may be imaged from below by the lens imaging mechanism 130. By calculating the luminance of the captured image, the contamination amount of the cover glass 113 may be quantified.

A specific method of quantifying the contamination amount of the cover glass 113 will be explained.

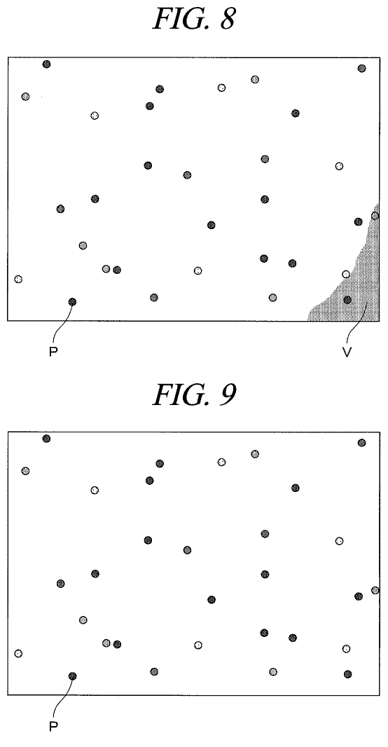

The image captured by the lens imaging mechanism 130 has a contaminated portion to which a particle P resulting from the laser processing is attached, and a non-contaminated portion with no particle P attached, as illustrated in FIG. 8. Also, the image captured by the lens imaging mechanism 130 has a shadowed region V resulting from the angle of view of the camera of the lens imaging mechanism 130, or the like, as shown in FIG. 8.

When quantifying the contamination amount, the brightness and the contrast of the captured image are first adjusted to eliminate the shadowed region V formed in the captured image, as shown in FIG. 9. If the quantification of the contamination amount is conducted without eliminating this shadowed region V, there is a risk that this shadowed region V may be erroneously identified as a contaminated portion.

Subsequently, the captured color image with the adjusted brightness and contrast is converted to a grayscale to be binarized into two tones (two-tone monochrome). In other words, the captured image, which is originally expressed in RGB values (each ranging from 0 to 255), is expressed in luminance values (0 to 255) of the two-tone monochrome. In the grayscale image, the luminance decreases (resulting in a stronger black component) at the contaminated portion with the particle P attached thereto, whereas the luminance increases (resulting in a stronger white component) at the non-contaminated portion with no particle P attached thereto.

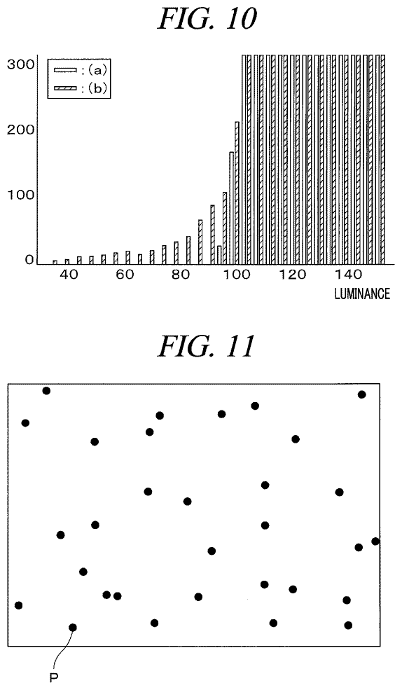

Subsequently, as shown in FIG. 10, luminance histograms (frequency distributions) of the grayscale image are created. (a) in FIG. 10 presents the histogram before the laser processing (initial values), and (b) in FIG. 10 provides the histogram after 100 sheets of combined wafers T (first wafers W) are processed.

As shown in FIG. 10, in the histogram (a) before the laser processing, the distribution is biased toward high luminance values because no particle P is attached to the cover glass 113. In the histogram (b) after the laser processing, on the other hand, the distribution is dispersed even at low luminance values because the particles P are attached to the cover glass 113. In other words, new luminance values appear in the histogram as a result of the particles P adhering to the cover glass 113 due to the laser processing.

Subsequently, by using a boundary between the low luminance side and the high luminance side in the histogram (b) after the laser processing in FIG. 10 (for example, luminance value of 100 in FIG. 10), that is, a newly generated luminance value as a threshold value, the captured image is binarized. In other words, the luminance value is unified as 255 (white) on the high luminance side of the histogram, which is assumed to be the portions of the cover glass 113 to which no particle P is attached, and the luminance value is unified as 0 (black) on the low luminance side of the histogram, which is assumed to be the portions of the cover glass 113 where the particles P are attached. As a result, the captured image is converted into a simplified image in which only the contaminated portions on the cover glass 113 are extracted as black (luminance value of zero (0)), as shown in FIG. 11.

Thereafter, by counting the total number of occurrences of the luminance representing the contaminated portion (hereinafter, referred to as total luminance count) (pixel count) from the binarized captured image, this total luminance count may be quantified as the contamination amount of the cover glass 113.

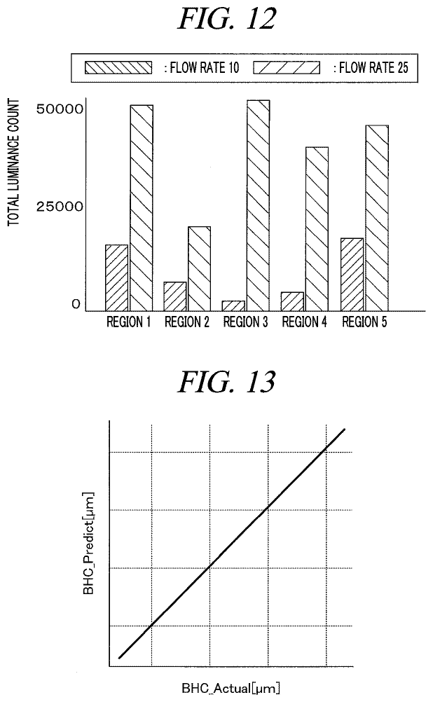

FIG. 12 is a histogram showing the contamination amounts (total luminance count) after processing 100 sheets of combined wafers T (first wafer W) when the gas flow rate from the nozzle 114 during the laser processing is set to be 10 m/s and 25 m/s, respectively. Further, regions 1 to 5 shown in FIG. 12 are arbitrary regions on a front surface of the cover glass 113, and the total luminance count is calculated for each of these regions. As can be seen from FIG. 12, the contamination amount (total luminance count) on the cover glass 113 tends to increase with a rise of the flow rate, and this is deemed to be because the particles P on the first wafer W are swept upwards as the flow rate of the gas increases, as stated above.

The contamination amount on the cover glass 113 is quantified as described above.

Instead of the total luminance count (pixel count) of the contaminated portions counted from the binarized captured image, by calculating a ratio of the area of the contaminated portions that can be calculated from the total luminance count, the contamination amount on the cover glass 113 may be quantified.

Specifically, after counting the total luminance count (pixel count) of the contaminated portions from the binarized captured image as described above, the contamination amount can be quantified by calculating a ratio of the area [pixel²] of the counted contaminated portions to the total area [pixel²] of the captured image based on the following expression (1). For example, the total area of the captured image can be calculated by multiplying the number of vertical pixels [pixel] and the number of horizontal pixels [pixel] of the captured image. The area of the contaminated portions can be calculated by multiplying a unit area [pixel²] of pixels where the contamination is countable by the total luminance count[-].

Contamination amount [%]=(Area of contaminated portions [pixel²]/Captured image [pixel²])×100 (1)
Area of contaminated portions [pixel²]=Unit area [pixel²]×Total luminance count (-)
Area of contaminated portions [pixel²]=Number of vertical pixels [pixel]×Number of horizontal pixels [pixels] of captured image

In the above example, though the contamination amount of the cover glass 113 is quantified based on the image of the cover glass 113 captured by the lens imaging mechanism 130, the acquisition of the captured image of the cover glass 113 does not have to be performed by the lens imaging mechanism 130. By way of example, instead of imaging the cover glass 113 by the lens imaging mechanism 130 inside the internal modifying apparatus 60, an operator may remove the cover glass 113 from the laser radiation device 110, and the captured image may be obtained outside the internal modifying apparatus 60.

After the various data for creating the approximate expression are acquired, the acquired various data are then input to acquire the correlation data between the flow rate of the gas from the nozzle 114, the number of processed combined wafers T (first wafers W), the contamination amount of the cover glass 113, and the BHC.

Specifically, by performing multiple regression analysis with the BHC (the length of the crack C extending toward the front surface Wa from the peripheral modification layer M1 formed at the lowermost side by the laser processing) as an objective variable and the flow rate of the gas, the number of processed wafers, and the contamination amount as explanatory variables, the following approximate expression (2) is derived (process St2 in FIG. 7).

γ=αx1+βx2+γx3+δ (2)

In the above equation, γ denotes the BHC, which is the objective variable; x1 to x3 denote one of the flow rate of the gas, the number of the processed wafers, and the contamination amount, which are the explanatory variables; α to γ denote coefficients of the explanatory variables; and δ denotes an intercept. Here, as the contamination amount, which is the explanatory variable, a quantified value obtained from either the total luminance count of the grayscale or the ratio of the area of the contaminated region mentioned above may be used.

The inventors of the present application have conducted intensive research and found that, as shown in FIG. 13, there is a high degree of agreement between an estimated BHC value (vertical axis) obtained from the above approximate expression (2) and an actual BHC value (horizontal axis) after the laser processing. In view of such a high degree of agreement, it is found out that a result of the BHC (the length of the crack C) can be estimated from the flow rate of the gas, the number of processed wafers, and the contamination amount that are acquired as the various data.

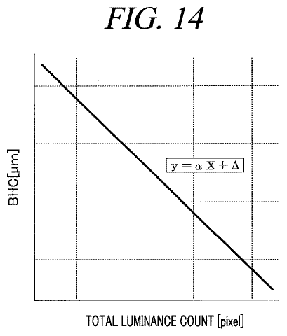

More specifically, the flow rate of the gas and the number of processed wafers used as the explanatory variables x in the above approximate expression (2) can be treated as constants that are determined based on the recipe and the processed result. Therefore, the above approximate expression (2) can be expressed as the following expression (3), and can be regarded as a linear function expressed in terms of the BHC and the contamination amount (luminance) of the cover glass 113, as shown in FIG. 14.

γ=αxΔ (3)

In the above expression, γ denotes the BHC, which is the objective variable; x denotes the contamination amount, which is the explanatory variable; a denotes α coefficient of the explanatory variable; and Δ denotes an intercept including the flow rate of the gas and the number of processed wafers as the constants.

The inventors of the present application have found that by quantifying the contamination amount on the cover glass 113 and performing the multiple regression analysis as described above, the BHC can be estimated from the above expression (3), and that the contamination amount (luminance or ratio of area) of the cover glass 113 can be determined by the above-described quantification method based on the flow rate of the gas and the number of processed wafers.

Once the above approximate expression (2) is obtained through the multiple regression analysis, a target specification of the BHC (hereinafter, sometimes referred to as “BHC specification”) is input (process St3 in FIG. 7). The “BHC specification” is the minimum length of the crack C required to allow the crack C1 to reach the front surface Wa of the first wafer W, which is opposite the surface irradiated with the laser light, in other words, a threshold value of the length (BHC) of the crack C for appropriately removing the peripheral portion We. The BHC specification may be manually input by, for example, the operator, or may be automatically input based on the processing recipe, etc.

If the BHC specification is input to the apparatus, the laser processing of the combined wafer T (first wafer W) in the internal modifying apparatus 60 is begun (process St4 in FIG. 7). That is, the internal laser light is applied to the inside of the first wafer W, thereby forming the peripheral modification layer M1. At this time, inside the first wafer W, the crack C1 develops from the peripheral modification layer M1 in the thickness direction of the first wafer W.

Also, when the laser processing is performed in this way, the cumulative number of processed combined wafers T (first wafers W) as one of the aforementioned various data is updated.

Furthermore, concurrently with or following the initiation of this laser processing, an estimated value of the BHC after the laser processing in the process St4 is calculated from the above approximate expression (2) (process St5 in FIG. 7). Once the estimated value of the BHC is calculated, this estimated value is compared with the BHC specification input in the process St3 (specification determination) (process St6 in FIG. 7).

If the comparison result indicates that the BHC meets the specification, that is, if it is determined that the estimated value of the BHC is equal to or higher than the BHC specification so that the edge trimming can be performed appropriately, the operation of the internal modifying apparatus 60 is carried on (process St7 in FIG. 7). In this case, the laser processing on the next combined wafer T (first wafer W) may be continuously performed, or the data on the number of processed wafers may be updated and the approximate expression (2) may be calculated again. In other words, the calculation of the above approximate expression (2) may be performed on a sheet-by-sheet basis for the combined wafers T that are processed by the internal modifying apparatus 60, or may be performed on a multiple-sheet basis (e.g., for each lot).

If, on the other hand, the comparison result indicates that the BHC does not meet the specification, that is, if it is determined that the estimated value of the BHC does not meet the BHC specification and the edge trimming cannot be performed appropriately, an alarm is issued to the operator, and maintenance of the internal modifying apparatus 60 is performed (process St8 in FIG. 7).

To elaborate, in the present exemplary embodiment, since it is determined based on the above approximate expression (2) that the crack C does not develop appropriately within the first wafer W due to the contamination amount on the cover glass 113, the cover glass 113 is removed from the laser radiation device 110 to be replaced or cleaned. As a result, the contamination amount on the cover glass 113 is improved, and the estimated value of the BHC is updated. Based on this, the laser processing of the combined wafer T (first wafer W) (process St4 in FIG. 7) is resumed.

The management and the control of the laser processing in the internal modifying apparatus 60 according to the present exemplary embodiment is performed as described above. According to the above-described exemplary embodiment, by estimating the result of the BHC after the laser processing from the flow rate of the gas from the nozzle 114, the number of processed combined wafers T, and the contamination amount on the cover glass 113, more broadly, by obtaining the correlation data between the flow rate of the gas from the nozzle 114, the number of processed combined wafers T (first wafers W), the contamination amount on the cover glass 113, and the result of the BHC after the laser processing, it is possible to determine, prior to carrying out the laser processing of the combined wafer T, whether or not the edge trimming of the first wafer W can be appropriately performed.

If it is determined that the edge trimming of the first wafer W cannot be performed appropriately, that is, if the estimated BHC value falls out of the BHC specification, an alarm is issued in advance, and the timing for the maintenance of the apparatus can be appropriately determined.

In the above-described exemplary embodiment, the flow rate of the gas, the number of processed wafers, and the contamination amount are used as the explanatory variables for calculating the approximate expression (2). However, the number of processed combined wafers T (first wafers W) may be omitted appropriately in the calculation of the approximate expression (2).

Also, in the above-described exemplary embodiment, the calculation of the estimated BHC value (process St5) is performed at least after the initiation of the laser processing on the combined wafer T (process St4). In this case, if it is determined that the estimated BHC value does not meet the BHC specification, since the crack C is not appropriately formed inside the combined wafer T that has been laser-processed in the process St4, the edge trimming of this combined wafer T cannot be properly performed.

In view of this, the calculation of the estimated BHC value (process St5) may be performed before the initiation of the laser processing on the combined wafer T (process St4). This allows the laser processing to be started after the estimated BHC value is calculated and compared with the BHC specification, thereby suppressing a decrease in the yield in the internal modifying apparatus 60.

In addition, in the above-described exemplary embodiment, the estimated BHC value calculated from the above approximate expression (2) is used to determine whether the edge trimming can be performed appropriately. Instead of this, however, the number of processed combined wafers T (first wafers W) that can ensure the BHC specification may be estimated based on the estimated BHC value.

In this case, if the sum of “the cumulative number of processed combined wafers T that have been processed since the previous cleaning (maintenance) of the cover glass 113 is performed” and “the number of combined wafers T to be processed in the internal modifying apparatus 60 from the current point onward” is equal to or less than “the estimated number of processable combined wafers T that can ensure the BHC specification (hereinafter referred to as “estimated number of processable wafers”), the processing in the internal modifying apparatus 60 is begun. On the other hand, if the sum exceeds the estimated number of processable wafers, an alarm may be issued to the operator, and maintenance of the internal modifying apparatus 60 (cleaning of the cover glass 113) may be performed without starting the processing in the internal modifying apparatus 60.

Alternatively, when the sum exceeds the estimated number of processable wafers, instead of immediately performing the maintenance of the internal modifying apparatus 60, it may be calculated from a difference between the cumulative number of processed wafers and the estimated number of processable wafers how many more combined wafers T can be processed before the estimated number of processable wafers is reached. In this case, the internal modifying apparatus 60 may resume the processing of the combined wafers T until the cumulative number of processed wafers reaches the estimated number of processable wafers, and after the cumulative number of processed wafers reaches the estimated number of processable wafers, maintenance of the internal modifying apparatus 60 (cleaning of the cover glass 113) may be performed.

Also, in this case, the timing of issuing the alarm to the operator is not limited to the time when it is confirmed that the sum exceeds the estimated number of processable wafers. By way of example, the alarm may be issued after the cumulative number of processed wafers reaches the estimated number of processable wafers after the resumption of processing in the internal modifying apparatus 60, or before the cumulative number of processed wafers reaches the estimated number of processable wafers after the resumption of processing in the internal modifying apparatus 60. In the latter case, the alarm may be set forth when the cumulative number of processed wafers reaches a value obtained by subtracting a set number of wafers from the estimated number of processable wafers.

In the above-described exemplary embodiment, the multiple regression analysis is performed with the result of the BHC after the laser processing as the objective variable and the flow rate of the gas, the number of processed wafers, and the contamination amount as the explanatory variables in the above approximate expression (2). However, when the result of the BHC after the laser processing can be measured or observed, for example, based on the calculated estimated value of the BHC, other data may be set as the objective variable.

Specifically, the approximate expression may be created by performing the multiple regression analysis with the contamination amount of the cover glass 113 as the objective variable y and the flow rate of the gas, the number of processed wafers and the BHC as the explanatory variables x. In other words, the contamination amount on the cover glass 113 may be estimated using the approximate expression in correlation with the flow rate of the gas and the actual number of processed wafers in the laser processing.

Even in this case, since the approximate expression can be expressed as a linear function of the contamination amount of the cover glass 113 and the BHC as shown in FIG. 14, the contamination amount of the cover glass 113 can be appropriately estimated from the BHC.

In this case, if the sum of “the cumulative number of processed combined wafers T that have been processed since the previous cleaning (maintenance) of the cover glass 113 is performed” and “the number of combined wafers T to be processed in the internal modifying apparatus 60 from the current point onward” is within “the number of processable combined wafers T (estimated number of processable wafers) that can ensure a contamination amount (luminance or contamination area) of the cover glass 113 that is assumed to be of a level where the edge trimming can be appropriately performed (the crack C1 can be formed to have a target length within the first wafer W)”, the processing in the internal modifying apparatus 60 is begun. On the other hand, if the sum exceeds the estimated number of processable wafers (exceeds the contamination amount of the cover glass 113 assumed to be of the level where the crack C1 can be formed to have the target length within the first wafer W), an alarm may be issued to the operator, and maintenance of the internal modifying apparatus 60 (cleaning of the cover glass 113) may be performed without starting the processing in the internal modifying apparatus 60.

Alternatively, if the sum exceeds the estimated number of processable wafers, instead of immediately performing the maintenance of the internal modifying apparatus 60, it can be calculated from the difference between the cumulative number of processed wafers and the estimated number of processable wafers how many more combined wafers T can be processed before the estimated number of processable wafers is reached. In this case, the internal modifying apparatus 60 may resume the processing of the combined wafers T until the cumulative number of processed wafers reaches the estimated number of processable wafers, and after the cumulative number of processed wafers reaches the estimated number of processable wafers, maintenance of the internal modifying apparatus 60 (cleaning of the cover glass 113) may be performed. Also, the timing of issuing the alarm to the operator is not particularly limited, as stated above.

In other words, the processing may be resumed when it is determined that the estimated contamination amount of the cover glass 113 after the completion of the processing of the combined wafers T as many as the sum of the cumulative number of processed combined wafers T and the number of combined wafers T to be processed from the current point onward is equal to or less than the contamination amount of the cover glass 113 that is assumed to be of the level where the edge trimming can be appropriately performed (the crack C meeting the BHC specification can be formed). On the other hand, if it is determined that the estimated contamination amount of the cover glass 113 after the completion of the processing of the combined wafers T as many as the sum exceeds the contamination amount of the cover glass 113 that is assumed to be of the level where the edge trimming can be performed appropriately, an alarm may be issued to the operator, and maintenance of the internal modifying apparatus 60 (cleaning of the cover glass 113) may be performed without starting the processing in the internal modifying apparatus 60.

The above exemplary embodiment has been described for the case of controlling the laser processing based on the aforementioned correlation data when processing, in the internal modifying apparatus 60, the combined wafer T in which the first wafer W and the second wafer S are bonded to each other. However, the technology disclosed herein is also applicable to other types of wafer processing.

By way of example, the technology of the present disclosure can be applied to a wafer processing in which laser light is applied to a single wafer (a wafer which is not bonded to another wafer) to form a modification layer and develop a crack from the modification layer, other than the processing of the combined wafer T in which the first wafer W and the second wafer S are bonded.

Also, the technology of the present disclosure can be applied to a case of splitting a wafer into multiple chips by developing a crack in a thickness direction of the wafer through irradiation of laser light, that is, a case of performing so-called wafer dicing.

In this case, instead of the above-described BHC (the length of the crack C that develops toward the front surface Wa from the peripheral modification layer M1 formed at the lowermost side by the laser processing), “the length of a crack as a requisite (target) for a dicing processing, which is formed in a wafer by a laser processing” may be used as a variable in the above-described approximate expression (2).

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

### EXPLANATION OF CODES

1: Wafer processing system
60: Internal modifying apparatus
90: Control device
112: Condenser lens
113: Cover glass
114: Nozzle
C1: Crack
M1: Peripheral modification layer
W: First wafer
We: Peripheral portion

1. A substrate processing method of processing a substrate, comprising:
applying laser light to the substrate to form a modification layer and a crack that develops in a thickness direction of the substrate from the modification layer;
acquiring data on a cumulative number of processed substrates, a contamination amount on a cover glass that protects a condenser lens configured to focus the laser light, a flow rate of a gas supplied along a bottom surface of the cover glass, and a length of the crack that develops due to the applying of the laser light; and
controlling the applying of the laser light based on the acquired data.

2. The substrate processing method of claim 1, further comprising:
creating, from the data, an approximate expression in which the length of the crack that develops due to the applying of the laser light is estimated;
inputting a specification value, which is a minimum length of the crack, the minimum length of the crack being required to allow the crack to reach a surface of the substrate opposite to a surface of the substrate irradiated with the laser light; and
calculating, from the approximate expression, an estimated value of the length of the crack after the applying of the laser light.

3. The substrate processing method of claim 2,
wherein when it is determined that the estimated value meets the specification value, the applying of the laser light is started, and
when it is determined that the estimated value does not meet the specification value, cleaning of the cover glass is started.

4. The substrate processing method of claim 1, further comprising:
creating, from the data, an approximate expression in which the length of the crack that develops due to the applying of the laser light is estimated;
inputting a specification value, which is a minimum length of the crack, the minimum length of the crack being required to allow the crack to reach a surface of the substrate opposite to a surface of the substrate irradiated with the laser light; and
estimating, from the approximate expression, a number of substrates to be processed, which is allowed to secure the specification value.

5. The substrate processing method of claim 4,
wherein when it is determined that a sum of the cumulative number of processed substrates and a number of substrates to be processed from a current point onward is equal to or less than the estimated number of substrates to be processed, the applying of the laser light is started, and
when it is determined that the sum exceeds the estimated number of substrates to be processed, cleaning of the cover glass is started.

6. The substrate processing method of claim 4,
wherein when it is determined that a sum of the cumulative number of processed substrates and a number of substrates to be processed from a current point onward is equal to or less than the estimated number of substrates to be processed, the applying of the laser light is started, and
when it is determined that the sum exceeds the estimated number of substrates to be processed, the substrates are processed until the cumulative number of processed substrates reaches the estimated number of substrates to be processed, and, then, cleaning of the cover glass is started.

7. The substrate processing method of claim 1, further comprising:
creating, from the data, an approximate expression in which the contamination amount on the cover glass is estimated; and
estimating the contamination amount on the cover glass with the approximate expression in correlation with a number of processed substrates.

8. The substrate processing method of claim 7,
wherein when it is determined that an estimated value of the contamination amount on the cover glass after completion of a processing on substrates as many as a sum of the cumulative number of processed substrates and a number of substrates to be processed from a current point onward is equal to or less than a contamination amount on the cover glass that is assumed be of a level where the crack can be formed in the substrate to have a target length, the applying of the laser light is started, and
when it is determined that the estimated value of the contamination amount on the cover glass after the completion of the processing on the substrates as many as the sum exceeds the contamination amount on the cover glass assumed to be of the level where the crack can be formed in the substrate to have the target length, cleaning of the cover glass is started.

9. The substrate processing method of claim 7,
wherein when it is determined that an estimated value of the contamination amount on the cover glass after completion of a processing on substrates as many as a sum of the cumulative number of processed substrates and a number of substrates scheduled to be processed from a current point onward is equal to or less than a contamination amount on the cover glass that is assumed be of a level where the crack can be formed in the substrate to have a target length, the applying of the laser light is started, and
when it is determined that the estimated value of the contamination amount on the cover glass after the completion of the processing on the substrates as many as the sum exceeds the contamination amount on the cover glass assumed to be of the level where the crack can be formed in the substrate to have the target length, the substrates are processed until the estimated value of the contamination amount on the cover glass reaches the contamination amount on the cover glass that is assumed be of the level where the crack can be formed in the substrate to have the target length, and, then, cleaning of the cover glass is started.

10. The substrate processing method of claim 1, further comprising:
acquiring a captured image of the cover glass;
converting the captured image to a grayscale;
binarizing the captured image converted to the grayscale;
counting a total luminance count of the binarized captured image; and
calculating a ratio of an area of the total luminance count to an entire area of the captured image,
wherein the contamination amount on the cover glass is acquired, using either the total luminance count or the ratio of the area.

11. A substrate processing system of processing a substrate, comprising:
an internal modifying apparatus configured to apply laser light to the substrate to form a modification layer and a crack that develops in a thickness direction of the substrate from the modification layer; and
a control device and a program storage including a program,
wherein the internal modifying apparatus comprises:
a condenser lens configured to focus the laser light to the substrate;
a cover glass that protects a bottom surface of the condenser lens; and
a nozzle configured to supply a gas along a bottom surface of the cover glass, and
the program storage and the program are configured, with the control device, to acquire, in the internal modifying apparatus, data on a cumulative number of processed substrates, a contamination amount on the cover glass, a flow rate of the gas supplied from the nozzle, and a length of the crack that develops due to application of the laser light, and control the application of the laser light based on the acquired data.

12. The substrate processing system of claim 11,
wherein the program storage and the program are configured, with the control device, to perform:
creating, from the data, an approximate expression the length of the crack that develops due to the application of the laser light is estimated; and
calculating, from the approximate expression, an estimated value of the length of the crack after the application of the laser light.

13. The substrate processing system of claim 12,
wherein the program storage and the program are configured, with the control device, to perform:
starting the application of the laser light when it is determined that the estimated value meets a specification value, which is a minimum length of the crack that reaches, the minimum length of the crack being required to allow the crack to reach a surface of the substrate opposite to a surface of the substrate irradiated with the laser light; and
issuing an alarm for starting cleaning of the cover glass when it is determined that the estimated value does not meet the specification value.

14. The substrate processing system of claim 11,
wherein the program storage and the program are configured, with the control device, to perform:
creating, from the data, an approximate expression the length of the crack that develops due to the application of the laser light is estimated; and
estimating, from the approximate expression, a number of substrates to be processed, which is allowed to secure a specification value, which is a minimum length of the crack, the minimum length of the crack being required to allow the crack to reach a surface of the substrate opposite to a surface of the substrate irradiated with the laser light.

15. The substrate processing system of claim 14,
wherein the program storage and the program are configured, with the control device, to perform:
starting the application of the laser light when it is determined that a sum of the cumulative number of substrates and a number of substrates to be processed from a current point onward is equal to or less than the estimated number of substrates to be processed; and
issuing an alarm for starting cleaning of the cover glass when it is determined that the sum exceeds the estimated number of substrates to be processed.

16. The substrate processing system of claim 14,
wherein the program storage and the program are configured, with the control device, to perform:
starting the application of the laser light when it is determined that a sum of the cumulative number of processed substrates and a number of substrates to be processed from a current point onward is equal to or less than the estimated number of substrates to be processed; and
processing, when it is determined that the sum exceeds the estimated number of substrates to be processed, substrates until the cumulative number of processed substrates reaches the estimated number of substrates to be processed, and, then, issuing an alarm for starting cleaning of the cover glass.

17. The substrate processing system of claim 11,
wherein the program storage and the program are configured, with the control device, to perform:
creating, from the data, an approximate expression the contamination amount on the cover glass is estimated; and
estimating the contamination amount on the cover glass by using the approximate expression, in correlation with a number of processed substrates.

18. The substrate processing system of claim 17,
wherein the program storage and the program are configured, with the control device, to perform:
starting the application of the laser light when it is determined that an estimated value of the contamination amount on the cover glass after completion of a processing on substrates as many as a sum of the cumulative number of processed substrates and a number of substrates to be processed from a current point onward is equal to or less than a contamination amount on the cover glass that is assumed be of a level where the crack can be formed in the substrate to have a target length; and
issuing an alarm for starting cleaning of the cover glass when it is determined that the estimated value of the contamination amount on the cover glass after the completion of the processing on the substrates as many as the sum exceeds the contamination amount on the cover glass assumed to be of the level where the crack can be formed in the substrate to have the target length.

19. The substrate processing system of claim 17,
wherein the program storage and the program are configured, with the control device, to perform:
starting the application of the laser light when it is determined that an estimated value of the contamination amount on the cover glass after completion of a processing on substrates as many as a sum of the cumulative number of processed substrates and a number of substrates to be processed from a current point onward is equal to or less than a contamination amount on the cover glass that is assumed be of a level where the crack can be formed in the substrate to have a target length; and
processing, when it is determined that the estimated value of the contamination amount on the cover glass after the completion of the processing on the substrates as many as the sum exceeds the contamination amount on the cover glass assumed to be of the level where the crack can be formed in the substrate to have the target length, substrates until the estimated value of the contamination amount on the cover glass reaches the contamination amount on the cover glass that is assumed be of the level where the crack can be formed in the substrate to have the target length, and, then, issuing an alarm for starting cleaning of the cover glass.

20. The substrate processing system of claim 11,
wherein the program storage and the program are configured, with the control device, to perform:
acquiring a captured image of the cover glass;
converting the captured image to a grayscale;
binarizing the captured image converted to the grayscale;
counting a total luminance count of the binarized captured image; and
calculating a ratio of an area of the total luminance count to an entire area of the captured image, and
the contamination amount on the cover glass is acquired, using either the total luminance count or the ratio of the area.
